(19) United States
(12) Patent Application Publication
(10) Pub. No.: US 2026/0362602 A1
(43) Pub. Date: Nov. 12, 2026

(54) WIRING BOARD AND ELECTRONIC COMPONENT

(71) Applicant: KYOCERA Corporation, Kyoto-shi, Kyoto (JP)

(72) Inventor: Katsuhiko ONOUE, Kagoshima (JP)

(73) Assignee: KYOCERA Corporation, Kyoto-shi, Kyoto (JP)

(21) Appl. No.: 19/133,371

(22) PCT Filed: Nov. 28, 2023
(86) PCT No.: PCT/JP2023/042548

§ 371 Date: May 28, 2025

(30) Foreign Application Priority Data
Nov. 29, 2022 (JP) 2022-190538

(51) Int. Cl. H05K 1/181; H05K 1/02

(52) U.S. Cl. CPC H05K 1/181; H05K 1/0284; H05K 2201/10083

(57) ABSTRACT

A wiring board includes an insulating substrate and multiple mount electrodes located on a first surface of the insulating substrate. A SAW element is mounted on the multiple mount electrodes. The insulating substrate includes a protrusion in a range of the first surface. The range is surrounded by the multiple mount electrodes. The protrusion may have widths equal to or greater than half respective ones of longitudinal and lateral widths of the range surrounded by the mount electrodes. The protrusion may surround at least a part of a periphery of each mount electrode. The protrusion may be located at multiple positions separate from one another within the range surrounded by the mount electrodes. The protrusion may include a top surface in a protruding-surface shape.

### TECHNICAL FIELD

The present disclosure relates to a wiring board and an electronic component.

### BACKGROUND

In an electronic component with a movable part such as a vibratable component, sealing is applied by using resin or the like while ensuring a motion space. In Japanese Unexamined Patent Application Publication No. 2003-338729, a frame part made of resin is formed around a piezoelectric element, and then another resin with an elastic modulus lower than that of the resin is used for sealing.

### SUMMARY

In an aspect of the present disclosure, a wiring board includes an insulating substrate and multiple first electrodes. The multiple first electrodes are located on a first surface of the insulating substrate. A SAW (Surface Acoustic Wave) element is mounted on the multiple first electrodes. The insulating substrate includes a protrusion in a range of the first surface. The range is surrounded by the multiple first electrodes.

### BRIEF DESCRIPTION OF THE DRAWINGS

FIG. 1A is a perspective view for explaining an exterior configuration of an electronic component including a wiring board of this embodiment.

FIG. 1B is a plan view of a bottom surface of the wiring board.

FIG. 2A is a plan view of a top surface of the wiring board.

FIG. 2B is a sectional view of the electronic component.

FIG. 3A is a view of a wiring board of Variation 1.

FIG. 3B is a view of a wiring board of Variation 2.

FIG. 4A is a plan view of a wiring board of Variation 3.

FIG. 4B is a sectional view of the wiring board of Variation 3.

FIG. 5A is a sectional view of a wiring board of Variation 4.

FIG. 5B is a sectional view of a wiring board of Variation 5.

FIG. 6 is a view of a wiring board of Variation 6.

### DETAILED DESCRIPTION

Hereinafter, an embodiment is described based on the drawings.

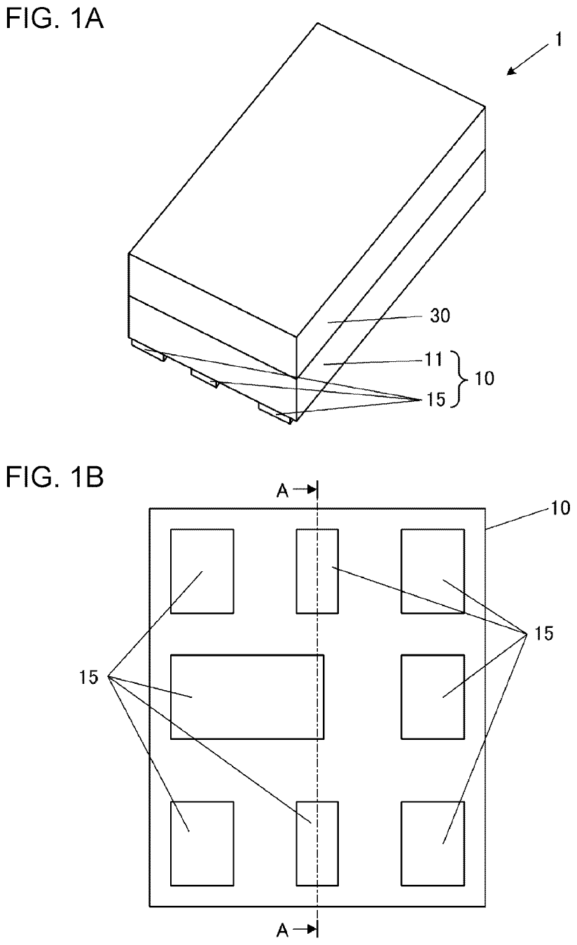

FIGS. 1A and 1B are views for explaining an exterior configuration of an electronic component 1 including a wiring board 10 of this embodiment. FIG. 1A is a perspective view of the electronic component 1. FIG. 1B is a plan view of a bottom surface of the electronic component 1.

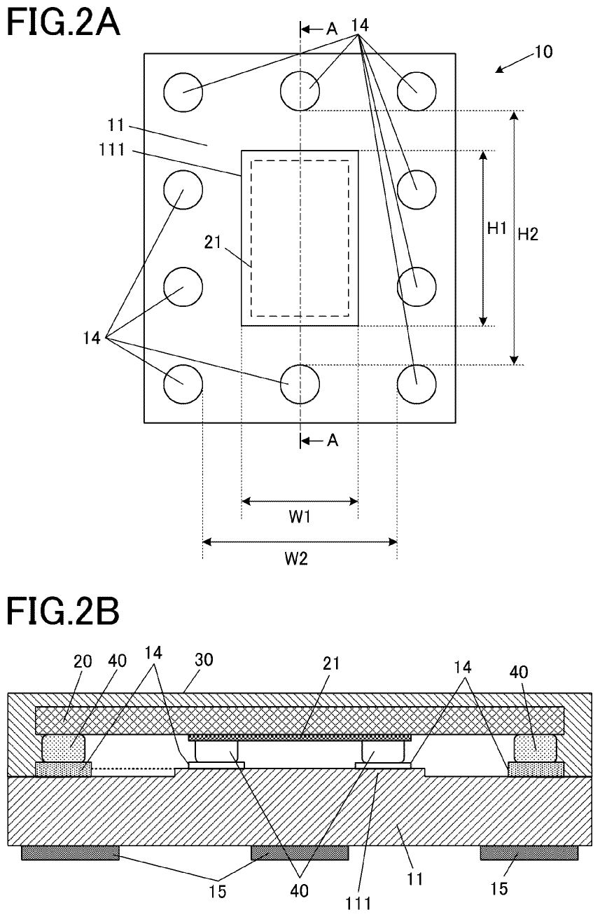

The electronic component 1 includes a wiring board 10 and a resin layer 30 exposed to an outside of the electronic component 1. For example, the wiring board 10 may include an electrode, and a signal line not illustrated, on a surface and/or inside of an insulating substrate 11. The insulating substrate 11 is, for example, a ceramic substrate made of a material such as an aluminum oxide-based sintered body (alumina ceramics), an aluminum nitride-based sintered body, a mullite-based sintered body, or a glass-ceramic sintered body. A SAW element 20, which will be described later (see FIG. 2B), is mounted on the wiring board 10. The electrode included in the wiring board 10 includes an outer electrode 15. The outer electrode 15 is located on a second surface that is a bottom surface of the insulating substrate 11 and couples the SAW element 20 to an external substrate and/or the like. The outer electrode 15 includes multiple outer electrodes 15 arranged at the bottom surface of the electronic component 1. The resin layer 30 covers the SAW element 20 at a top surface of the wiring board 10.

FIG. 2A is a plan view of the top surface of the wiring board 10. FIG. 2B is a sectional view of the electronic component 1 taken along line A-A illustrated in FIGS. 1B and 2A.

As illustrated in FIG. 2A, the wiring board 10 includes, in addition to the insulating substrate 11 and the outer electrode 15 described above, multiple mount electrodes 14 located on a top surface of the insulating substrate 11. The top surface of the insulating substrate 11 is a first surface opposite to the second surface. The mount electrode 14 corresponds to a first electrode of the present disclosure. The number of mount electrodes 14 is at least the number necessary for coupling the SAW element 20 and is not particularly limited. In an embodiment, the mount electrodes 14 may be arranged in a point-symmetrical manner with respect to a center of the insulating substrate 11. However, these mount electrodes 14 may not be arranged in a point-symmetrical manner due to, for example, partial omission of the mount electrodes 14, and/or non-uniformity of sizes and/or intervals of the mount electrodes 14. That is, the mount electrodes 14 are arranged in number and at positions appropriate for coupling a given SAW element 20. Note that the given SAW element 20 may be selected from different SAW elements in the same terminal arrangement. In the same and/or similar manner, a signal line, which is not illustrated, coupled to the mount electrode 14 also extends in a form appropriate to input/output signals from or to the SAW element 20.

The mount electrode 14 and the outer electrode 15 are conductive metal and may be, for example, gold, silver, copper, tungsten, molybdenum, manganese, palladium, platinum, or an alloy obtained by at least two of the aforementioned metals being combined together. For example, the mount electrode 14 and the outer electrode 15 may be formed on the insulating substrate 11 by screen printing or the like.

The insulating substrate 11 includes a protrusion 111 at a position surrounded by the mount electrodes 14 in plan view. The protrusion 111 protrudes above another portion of the first surface, that is, protrudes outwardly. This protrusion 111 has a rectangular shape in plan view. Lengths H1 and W1 of two sides of the protrusion 111 may be equal to or greater than half widths H2 and W2, respectively, of a region surrounded by the mount electrodes 14. Although, here, the region is a region coupling center positions of the respective mount electrodes 14, the region may be any range at least inscribed in the mount electrodes 14. Specifically, for example, when the substrate has a size of 2.5 mm×2.0 mm, the width H2 may be 2 mm and the width W2 may be 1.5 mm. Note that the rectangular shape in plan view as used herein may be a shape with some or all of vertexes rounded.

A surface of the protrusion 111 does not include thereon a structure other than the protrusion 111, such as a signal line or a component. The surface of the protrusion 111 is not applied with processing, such as coating, different from processing applied to a non-protruding portion. That is, the protrusion 111 simply protrudes from the first surface of the insulating substrate 11 in appearance.

As illustrated in the sectional view in FIG. 2B, the SAW element 20 is coupled to and mounted on the mount electrode 14 with a bump 40 interposed therebetween. For example, the bump 40 is solder, gold, or the like, but is not limited thereto.

The SAW element 20 includes a piezoelectric member that deforms in accordance with the application of a voltage signal. The piezoelectric member is appropriately determined in accordance with a frequency, a vibration mode, and/or the like. For example, the piezoelectric member may be a substrate including a single crystal with piezoelectricity, such as a lithium tantalate (LiTaO₃) single crystal or a lithium niobate (LiNbO₃) single crystal. The piezoelectric member of the SAW element 20 includes a bottom surface opposed to the wiring board 10. The bottom surface includes a comb-shaped electrode 21 receiving radio-frequency signals from one side and selectively outputting, from the other side, a signal in a desired frequency band among the received radio-frequency signals. The comb-shaped electrode 21 is also referred to as an interdigital electrode. The comb-shaped electrode 21 is a conductive member and may be, for example, Al or an Al alloy (Al—Cu-based alloy, Al—Ti-based alloy). For example, the comb-shaped electrode 21 may be formed on the piezoelectric member through a well-known thin-film formation technique, such as an evaporation method, a sputtering method, or a CVD (Chemical Vapor Deposition) method.

In an embodiment, the comb-shaped electrode 21 may be located in a range opposed to the protrusion 111. For example, as indicated by a broken line in FIG. 2A, the comb-shaped electrode 21 may be contained within the range of the protrusion 111 in plan view. The resin layer 30 covers an upper side and a side-surface side of the SAW element 20. Therefore, the SAW element 20 is not exposed to an outside.

For example, the resin layer 30 may be a thermosetting resin. For example, the thermosetting resin may be an epoxy resin, a phenolic resin, or the like. For example, the resin layer 30 may be formed through potting or the like, but is not limited thereto.

The comb-shaped electrode 21 and the protrusion 111 define an internal space therebetween. Accordingly, the resin layer 30 and/or the like do not reduce vibration of a surface acoustic wave (SAW) caused by the comb-shaped electrode 21. The surface acoustic wave may also be referred to as an elastic surface wave. A height of this internal space, that is, a distance between the comb-shaped electrode 21 in a stationary state and the protrusion 111 may be, for example, 0.03 mm. Note that, ideally, the resin layer 30 does not enter the range surrounded by the mount electrodes 14 in plan view. However, in effect, the resin layer 30 may slightly enter an inner side of the mount electrodes 14 when resin has low viscosity during covering. At this time, the entering resin component spreads on the insulating substrate 11 due to gravity. However, since the protrusion 111 suppresses spreading of the resin component, the resin does not spread into the range opposed to the comb-shaped electrode 21, which suppresses adhesion of the resin to the comb-shaped electrode 21. Note that this becomes meaningless when resin is supplied to an extent to spread onto the protrusion 111, and therefore an amount of resin to be supplied during formation of the resin layer 30 is appropriately controlled.

A height of the protrusion 111 protruding from the first surface of the insulating substrate 11 may be lower than a height of the mount electrode 14. That is, the protrusion 111 may be thinner than the mount electrode 14. The height of the protrusion 111 may be, for example, 0.01 mm. This height may be determined in accordance with viscosity of resin before thermosetting, and/or the like. The protrusion 111 having a height no larger than necessary allows the comb-shaped electrode 21 and the protrusion 111 to appropriately ensure a space therebetween.

A total area of the mount electrodes 14 in plan view is less than a total area of the outer electrodes 15 in plan view. A difference between a total area of the areas of the mount electrodes 14 in plan view and an area of the protrusion 111 in plan view, and the total area of the outer electrodes 15 in plan view is less than a difference between the total area of the mount electrodes 14 in plan view and the total area of the outer electrodes 15 in plan view. In this manner, the protrusion 111 provides further balancing in an up-down direction, and the wiring board 10, in particular, the insulating substrate 11 is less likely to warp.

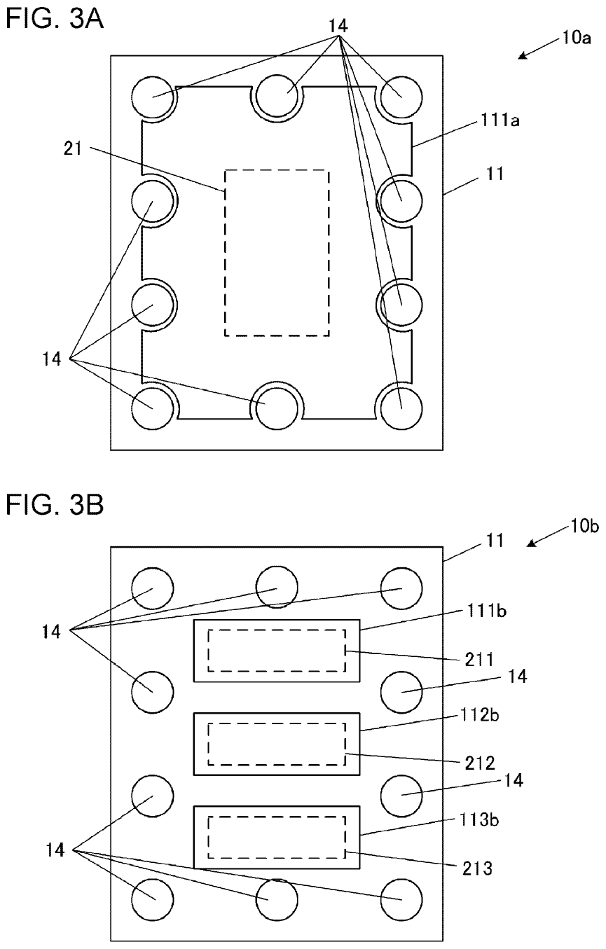

FIG. 3A is a view of Variation 1 of the wiring board 10 of this embodiment. FIG. 3B is a view of Variation 2 of the wiring board 10 of this embodiment.

As illustrated in FIG. 3A, a wiring board 10a of Variation 1 may include a protrusion 111a extending even between the multiple mount electrodes 14. In other words, the protrusion 111a may include recesses at positions corresponding to the ranges of the respective mount electrodes 14 in plan view. Accordingly, each mount electrode 14 in a circular shape in plan view has a positional relationship in which at least a part of its angular range is, here partially, surrounded by the protrusion 111a. Although not particularly limited, for example, the protrusion 111a may surround, by an angle of 45 degrees or more, the mount electrode 14 at a position forming a corner in the arrangement of the mount electrodes 14. The protrusion 111 a may surround, by an angle of 90 degrees or more, the mount electrode 14 at a position on a line connecting the adjacent mount electrodes 14 on both sides. Such a protrusion 111a can suppress flowing of resin with low viscosity into the region surrounded by the multiple mount electrodes 14 during formation of the resin layer 30.

As illustrated in FIG. 3B, a wiring board 10b of Variation 2 may include a protrusion divided into three protrusions 111b to 113b that are multiple parts separate from one another. In this electronic component 1, as indicated by broken lines, the SAW element 20 includes comb-shaped electrodes 211 to 213 also divided into three parts. The protrusions 111b to 113b may contain the ranges of the comb-shaped electrodes 211 to 213, respectively, in plan view.

Such a positional relationship between the multiple comb-shaped electrodes 211 to 213 and the multiple protrusions 111b to 113b appropriately reduces flowing of resin and adhering of resin to the comb-shaped electrodes 211 to 213 to a necessary extent. The number, a dimension, a size, a position, a direction, and the like of the comb-shaped electrodes 211 to 213 may appropriately be changed in accordance with design of the SAW element 20.

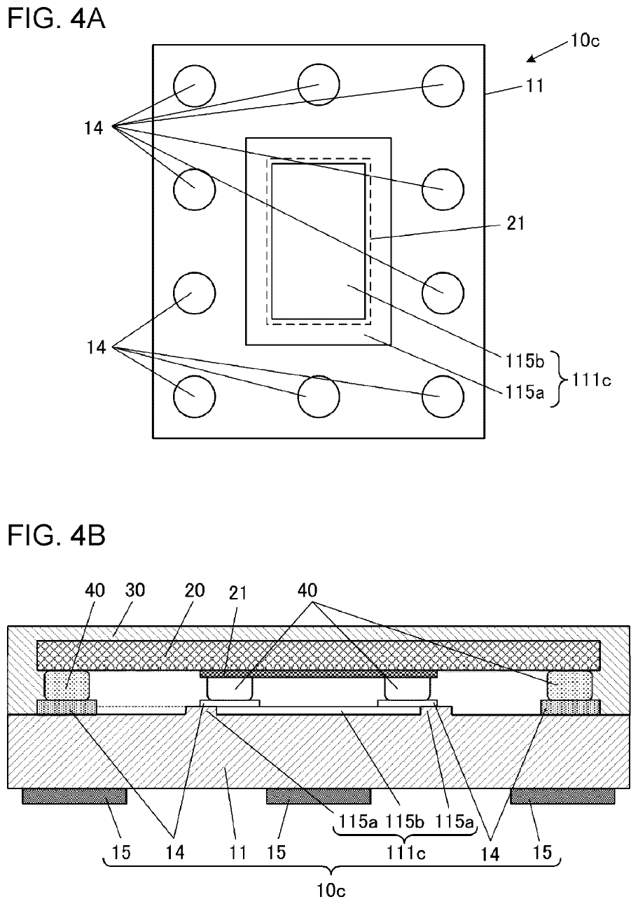

FIG. 4A is a plan view of a wiring board 10c of Variation 3. FIG. 4B is a sectional view of the wiring board 10c of Variation 3 in the same sectional plane as that illustrated in FIG. 2B.

The wiring board 10c may include a protrusion 111c in a frame-like shape. That is, the protrusion 111c may include a recess 115b at a center. As illustrated in FIG. 4B, a bottom surface of the recess 115b may be at the same height as another portion of the first surface of the insulating substrate 11. As illustrated in FIGS. 4A and 4B, here, the comb-shaped electrode 21 includes a portion overlapping a protruding frame-like portion 115a of the protrusion 111c in plan view, but is not limited thereto. The comb-shaped electrode 21 may overlap only the recess 115b in plan view, which ensures a sufficient space below the comb-shaped electrode 21. A width of the frame-like portion 115a may appropriately be set in accordance with an outer peripheral size of the above-described protrusion 111c and a size of the comb-shaped electrode 21 in plan view. This width is also not necessarily uniform.

Note that the height of the bottom surface of the recess 115b is not necessarily the same as a height of another upper-surface portion of the wiring board 10c as long as the height of the bottom surface of the recess 115b is lower than a height of the frame-like portion 115a. Each of an inner edge and an outer edge of the frame-like portion 115a does not necessarily have a rectangular shape in plan view. The inner edge and the outer edge of the frame-like portion 115a may each have a rectangular shape with a rounded corner or may have an ellipse shape. The inner edge and the outer edge of the frame-like portion 115a may have shapes different from one another in plan view.

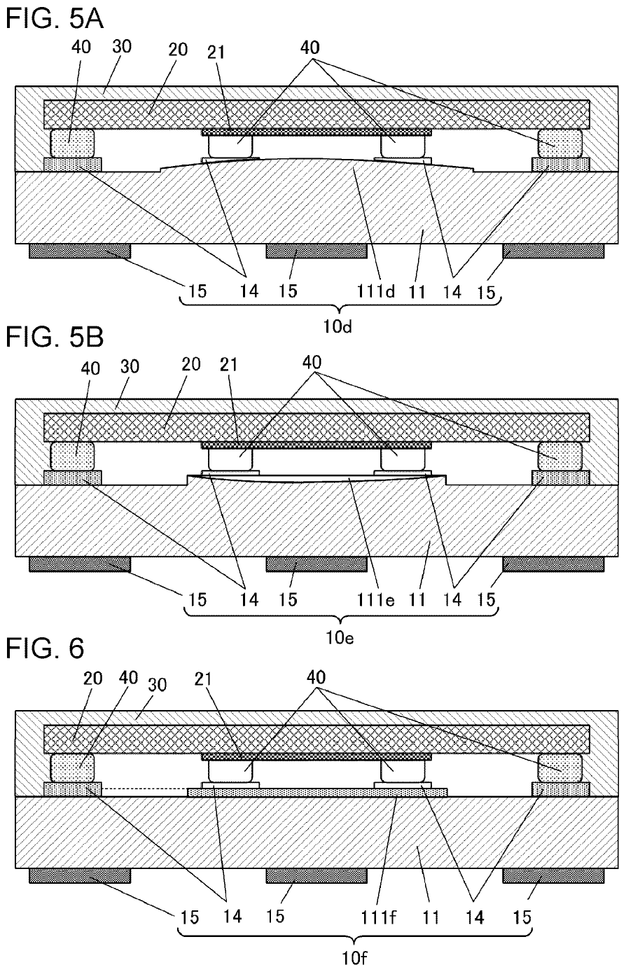

FIG. 5A is a sectional view of a wiring board 10d of Variation 4. FIG. 5B is a sectional view of a wiring board 10e of Variation 5. A sectional plane in these figures is the same position as that illustrated in FIG. 2B.

As illustrated in FIG. 5A, the wiring board 10d of Variation 4 may include a protrusion 111d with a top surface in a protruding shape. That is, a height of the protrusion 111d may be low at a peripheral edge thereof and increase toward a center in plan view. The top surface of the protrusion 111d may form a curved surface, for example, a hyperboloid surface, in sectional view. Alternatively, the top surface of the protrusion 111d may have a triangular shape, for example, a conical shape, in sectional view. Alternatively, the protrusion 111d is not necessarily point-symmetric with respect to a center position in plan view.

Also in this case, the peripheral edge of the protrusion 111d may include a step between the peripheral edge and a top surface of the wiring board 10d. Accordingly, resin can be less likely to climb up onto the protrusion 111d in a continuous manner.

As illustrated in FIG. 5B, the wiring board 10e of Variation 5 may include a protrusion 11le with a top surface in a recessed shape. That is, a height of the protrusion 111e may be the highest at a peripheral edge thereof and decrease toward a center. The height at the center may be equal to or higher than a height of a top surface of the wiring board 10e. A shape of the top surface of the protrusion 111e may be a hyperboloid surface, or may be a funnel shape, that is, an inverted conical shape. The protrusion 111e is not necessarily point-symmetric with respect to a center position in plan view.

The shapes in the above-described variations may be combined, and, for example, a protrusion with a frame-like portion may include the frame-like portion with a boundary inclined in a bank-like shape. When the height of the protrusion 111d, 111e, or the like is nonuniform as in Variations 4 and 5, the shape of the protrusion 111d, 111e, or the like in plan view is not necessarily limited to a simple shape, such as a rectangular shape, a circular shape, an ellipse shape, or the like.

FIG. 6 is a sectional view of a wiring board 10 f of Variation 6. A sectional plane in the figure is the same position as that illustrated in FIG. 2B.

In an embodiment, the wiring board 10f may include a protrusion 111f that is the same metal layer as the mount electrode 14. That is, the protrusion 111f may be made of a material different from the insulating substrate 11. Such a protrusion 111f may have the same shape as any of the protrusions 111a to 111e having the shapes described in Variations 1 to 5. In the same and/or similar manner as/to the protrusions 111 to 111e, the protrusion 111f does not contact any structure other than the protrusion 111f, such as a signal line, a component, or an electrode. In manufacturing, the protrusion 111f can easily be provided to the first surface, which is a flat surface, of the insulating substrate 11. Further, when the protrusion 111f is made of the same material as the mount electrode 14, time and effort and costs decrease.

As described above, each of the wiring boards 10 to 10f of this embodiment includes the insulating substrate 11 and the multiple mount electrodes 14 located on the first surface of the insulating substrate 11. The SAW element 20 is mounted on the multiple mount electrodes 14. The insulating substrate 11 includes any one of the protrusions 111 to 111f in a range of the first surface. The range is surrounded by the multiple mount electrodes 14. The protrusion may not be integral with the insulating substrate 11 similarly to the protrusion 111f. Accordingly, flowing of resin into the range of the protrusions 111 to 111f is suppressed during formation of the resin layer 30. Therefore, the wiring boards 10 to 10f can reduce effect on operation of the SAW element 20 due to adhesion of resin to a vicinity of the comb-shaped electrode 21 of the SAW element 20.

In particular, as the resin layer 30 has a reduced thickness in accordance with a reduction in height, resin with low viscosity and favorable processability before thermosetting may be used as resin used for the resin layer 30. However, resin with low viscosity easily enters a narrow gap to be ensured and may adhere to and thus have influence on a component and/or the like. According to the technology of the present disclosure, resin is less likely to enter a gap to be ensured. Therefore, control for suppressing flowing of resin and adhering of resin to a vicinity of a component such as the comb-shaped electrode 21 requires less time and effort, which simplifies a manufacturing process.

Even when a height reduction, which is important for module mounting of the SAW element 20, is performed, vibration by a SAW temporarily converted from a signal is stably obtainable. Therefore, use of the wiring boards 10 to 10f does not cause decline in a function of a SAW filter, a duplexer, and/or the like that are module-mounted.

Each of the protrusions 111, 111a, and 111c to 111f has the widths (H1 and W1) equal to or greater than half the respective ones of the longitudinal and lateral widths (H2 and W2) of the range. Each of the protrusions 111, 111a, and 111c to 111f has the size determined corresponding to a size of a SAW element basically defined as an attachment target in advance. When the protrusions 111, 111a, and 111c to 111f have a sufficient size relative to the comb-shaped electrode 21 in plan view, a reduced amount of resin can adhere to the comb-shaped electrode 21 and surroundings of the comb-shaped electrode 21.

The protrusion 111a may surround at least a part of a periphery of each of the multiple mount electrodes 14. The protrusion 111a in such a shape can cover a large portion of the range surrounded by the mount electrodes 14 to an extent without contacting the protrusion 111a. Therefore, a further reduced amount of resin can adhere to the mount electrode 14.

The protrusions 111b to 113b may be located at multiple positions separate from one another within the range surrounded by the mount electrodes 14. As in a duplexer or the like, when the comb-shaped electrode 21 includes multiple comb-shaped electrodes 21 of a SAW filter, the insulating substrate 11 may include multiple protrusions corresponding to positions of the multiple comb-shaped electrodes 21 in plan view. Accordingly, an effectively reduced amount of resin can adhere to each comb-shaped electrode 21.

The protrusion 111d includes the top surface in a protruding-surface shape. Even in such a shape, when entering of resin into the portion opposed to the comb-shaped electrode 21 is suppressed, a reduced amount of resin can adhere to the comb-shaped electrode 21.

Alternatively, the protrusion 111e includes the top surface in a recessed-surface shape. When the peripheral edge of the protrusion 111e can be high to suppress entering of resin to the inner side, a reduced amount of resin can adhere to the comb-shaped electrode 21 even when the protrusion 111e is not opposed to the entire comb-shaped electrode 21. Further, a large portion can have an increased distance between the comb-shaped electrode 21 and the insulating substrate 11, which can reduce obstruction of a SAW of the SAW element 20.

The protrusion 111c may have a frame-like shape. That is, as long as the frame-like portion 115a protrudes, an inner side of the frame-like portion 115a does not necessarily protrude from the first surface of the insulating substrate 11. The frame-like portion 115a is an outer frame of a range where resin is not to flow into. Accordingly, a portion of the comb-shaped electrode 21 located on the inner side of the frame-like portion 115a can certainly ensure a known, sufficient distance with respect to the insulating substrate 11.

Each of the protrusions 111 to 111f is thinner than each of the multiple mount electrodes 14. When the protrusions 111 to 111f are higher (thicker) than necessary, a space between the protrusions 111 to 111f and the comb-shaped electrode 21 is narrow. Therefore, the height of the protrusions 111 to 111f can be determined in such a manner as to maintain the space between the comb-shaped electrode 21 and the protrusions 111 to 111f without consideration of a height of the bump 40.

The wiring board 10 includes the multiple outer electrodes 15 located on the bottom surface opposite to the top surface. The total area of the multiple outer electrodes 15 in plan view is more than the total area of the multiple mount electrodes 14 in plan view. In this state, the protrusions 111 to 111f are further located on the top-surface side, and therefore attachments on both sides of the insulating substrate 11 can take a balance, which makes bending and/or the like less likely to occur.

The electronic component 1 of this embodiment includes the wiring board 10, the SAW element 20, and the resin layer 30. The SAW element 20 is coupled to the multiple mount electrodes 14 and includes the comb-shaped electrode 21. The comb-shaped electrode 21 is opposed to the protrusions 111 to 111f. The resin layer 30 covers the SAW element 20.

This electronic component 1 suppresses flowing of resin into a space between the comb-shaped electrode 21 and the insulating substrate 11 upon covering and sealing of the SAW element 20 by resin. Therefore, in the electronic component 1, resin is less likely to adhere to the comb-shaped electrode 21, and the electronic component 1 can cause the SAW element 20 to stably operate.

Note that the above-described embodiment is merely illustration, and various changes are possible.

For example, in the embodiment described above, the protrusion 111a includes the portion surrounding, in an arc-like shape, a part of the periphery of each mount electrode 14 in a circular shape in plan view, but is not limited thereto. The protrusion 111a may include a cutout or the like, for example, in a rectangular shape or a triangular shape in plan view so that the mount electrode 14 in a circular shape in plan view and the protrusion 111a do not overlap one another.

In the embodiment described above, the mount electrode 14 and the protrusion 111 do not contact one another. However, the mount electrode 14 and the protrusion 111 may contact one another as long as such contact does not affect a reduction in adhesion of resin and/or the like to the comb-shaped electrode 21, and the protrusion 111 is not a metal member like the protrusion 111f.

The protrusion 111 and the comb-shaped electrode 21 may have shapes different from one another in plan view as long as the protrusion 111 and the comb-shaped electrode 21 are opposed to one another. For example, the protrusion 111 may be located with a larger margin on an outer peripheral side of the wiring board 10 with respect to the position of the comb-shaped electrode 21 in plan view. That is, a center position of the protrusion 111 in plan view does not necessarily match a center position of the comb-shaped electrode 21 in plan view. The center positions in plan view may be two-dimensional, center of gravity positions of the protrusion 111 and the comb-shaped electrode 21.

A protrusion may have a shape different from the shapes illustrated as the protrusions 111 to 111f. The inside of the frame-like portion 115 a may also partially include a protrusion. A protrusion may include a dual structure including an outer frame inscribed in the mount electrodes 14 and a protrusion structure in a positional range opposed to the comb-shaped electrode 21 inside of the outer frame. A part or the entirety of a protrusion may not directly be opposed to the comb-shaped electrode 21. In particular, the above-described protrusion may be located at a position to obstruct flowing of resin into the range opposed to the comb-shaped electrode 21.

In Variation 2, the wiring board 10 includes the protrusions 111b to 113b corresponding to the multiple comb-shaped electrodes 211 to 213, respectively, but is not limited thereto. The wiring board 10 may include a common protrusion opposed to multiple comb-shaped electrodes. In this case, the protrusion may have various shapes, such as an L-shape, a U-shape, and a comb-like shape, in accordance with a positional relationship of the comb-shaped electrodes 211 to 213.

The protrusion 111 may have a height equal to or greater than the height of each mount electrode 14 in accordance with the height of the bump 40 and/or the like.

For example, multiple comb-shaped electrodes 21 each having a size smaller than a size of the range surrounded by the mount electrodes 14 may be located discretely. In this case, a protrusion may have a size smaller than, in particular, equal to or less than half the range.

A signal line, which is not illustrated, does not necessarily pass a surface or inside of the insulating substrate 11. The signal line may partially include intervention of a bonding wire, a lead, and/or the like.

In addition, contents of the specific configuration, structure, material, manufacturing method, and the like described in the embodiment are appropriately changeable without departing from the spirit of the present disclosure. The scope of the present invention includes the scope of the invention recited in the claims and its equivalent scope.

### INDUSTRIAL APPLICABILITY

The present disclosure is applicable to a wiring board and an electronic component.

### REFERENCE SIGNS

1 electronic component
10 to 10f wiring board
11 insulating substrate
111 to 111f, 112b, 113b protrusion
115a frame-like portion
115b recess
14 mount electrode
15 outer electrode
20 SAW element
21, 211 to 213 comb-shaped electrode
30 resin layer
40 bump

1. A wiring board comprising:
an insulating substrate; and
multiple first electrodes located on a first surface of the insulating substrate, a SAW element being mounted on the multiple first electrodes, wherein
the insulating substrate comprises a protrusion in a range of the first surface, the range being surrounded by the multiple first electrodes.

2. The wiring board according to claim 1, wherein the protrusion has widths equal to or greater than half respective ones of longitudinal and lateral widths of the range.

3. The wiring board according to claim 1, wherein the protrusion surrounds at least a part of a periphery of each of the multiple first electrodes.

4. The wiring board according to claim 1, wherein the protrusion is located at multiple positions separate from one another within the range.

5. The wiring board according to claim 1, wherein the protrusion comprises a top surface in a protruding-surface shape.

6. The wiring board according to claim 1, wherein the protrusion comprises a top surface in a recessed-surface shape.

7. The wiring board according to claim 1, wherein the protrusion has a frame-like shape.

8. The wiring board according to claim 1, wherein the protrusion is thinner than each of the multiple first electrodes.

9. The wiring board according to claim 1, further
comprising multiple second electrodes located on a second surface opposite to
the first surface, wherein
a total area of the multiple second electrodes in plan view is more than a total area of the multiple first electrodes in plan view.

10. An electronic component comprising:
the wiring board according to claim 1;
a SAW element comprising a comb-shaped electrode and coupled to the multiple first electrodes while the comb-shaped electrode is opposed to the protrusion; and
a resin layer covering the SAW element.

11. An electronic component comprising:
the wiring board according to claim 2;
a SAW element comprising a comb-shaped electrode and coupled to the multiple first electrodes while the comb-shaped electrode is opposed to the protrusion; and
a resin layer covering the SAW element.

12. An electronic component comprising:
the wiring board according to claim 3;
a SAW element comprising a comb-shaped electrode and coupled to the multiple first electrodes while the comb-shaped electrode is opposed to the protrusion; and
a resin layer covering the SAW element.

13. An electronic component comprising:
the wiring board according to claim 4;
a SAW element comprising a comb-shaped electrode and coupled to the multiple first electrodes while the comb-shaped electrode is opposed to the protrusion; and
a resin layer covering the SAW element.

14. An electronic component comprising:
the wiring board according to claim 5;
a SAW element comprising a comb-shaped electrode and coupled to the multiple first electrodes while the comb-shaped electrode is opposed to the protrusion; and
a resin layer covering the SAW element.

15. An electronic component comprising:
the wiring board according to claim 6;
a SAW element comprising a comb-shaped electrode and coupled to the multiple first electrodes while the comb-shaped electrode is opposed to the protrusion; and
a resin layer covering the SAW element.

16. An electronic component comprising:
the wiring board according to claim 7;
a SAW element comprising a comb-shaped electrode and coupled to the multiple first electrodes while the comb-shaped electrode is opposed to the protrusion; and
a resin layer covering the SAW element.

17. An electronic component comprising:
the wiring board according to claim 8;
a SAW element comprising a comb-shaped electrode and coupled to the multiple first electrodes while the comb-shaped electrode is opposed to the protrusion; and
a resin layer covering the SAW element.

18. An electronic component comprising:
the wiring board according to claim 9;
a SAW element comprising a comb-shaped electrode and coupled to the multiple first electrodes while the comb-shaped electrode is opposed to the protrusion; and
a resin layer covering the SAW element.
